(19) United States
(12) Patent Application Publication
(10) Pub. No.: US 2013/0260569 A1
(43) Pub. Date: Oct. 3, 2013

(54) APPARATUS AND METHOD FOR LIQUID TREATMENT OF WAFER-SHAPED ARTICLES

(71) Applicants: Michael GANSTER, ST. STEFAN (AT); Philipp ZAGORZ, VILLACH (AT); Alois GOLLER, VILLACH (AT)

(72) Inventors: Michael GANSTER, ST. STEFAN (AT); Philipp ZAGORZ, VILLACH (AT); Alois GOLLER, VILLACH (AT)

(73) Assignee: LAM RESEARCH AG, VILLACH (AT)

(21) Appl. No.: 13/435,356

(22) Filed: Mar. 30, 2012

(51) Int. Cl. H01L 21/306; H01L 21/30; B05C 5/02; B05C 21/00; B08B 3/10; B08B 3/14

(52) U.S. Cl. 438/745; 134/104.2; 134/104.4; 134/56 R; 134/10; 156/345.18; 156/345.15; 118/602; 118/696; 438/758; 257/E21.211; 257/E21.219

(57) ABSTRACT

An apparatus and method for liquid treatment of wafer-shaped articles comprises a process unit comprising a chuck for holding a wafer-shaped article in a predetermined orientation, and a liquid recovery system that receives used process liquid recovered from the process unit. The liquid recovery system supplies process liquid to a dispenser in the process unit. A supply of fresh process liquid supplies fresh process liquid to the liquid recovery system and also supplies fresh process liquid to a dispenser in the process unit while bypassing the liquid recovery system.

### BACKGROUND OF THE INVENTION

1. Field of the Invention

The invention relates generally to methods and apparatus for liquid treatment of wafer-shaped articles, such as semiconductor wafers, wherein one or more treatment liquids are dispensed onto a surface of the wafer-shaped article.

2. Description of Related Art

Semiconductor wafers are subjected to various surface treatment processes such as etching, cleaning, polishing and material deposition. To accommodate such processes, a single wafer may be supported in relation to one or more treatment fluid nozzles by a chuck associated with a rotatable carrier, as is described for example in U.S. Pat. Nos. 4,903,717 and 5,513,668.

Alternatively, a chuck in the form of a ring rotor adapted to support a wafer may be located within a closed process chamber and driven without physical contact through an active magnetic bearing, as is described for example in International Publication No. WO 2007/101764 and U.S. Pat. No. 6,485,531.

In either type of device, process liquids are dispensed onto one or both major surfaces of the semiconductor wafer as it is being rotated by the chuck. Such process liquids may for example be strong oxidizing compositions such as mixtures of sulfuric acid and peroxide for cleaning surfaces of the semiconductor wafer. Such process liquids typically also include deionized water to rinse the wafer between processing steps, and the deionized water is commonly supplemented with isopropyl alcohol to reduce the surface tension of the rinse liquid on the wafer.

Different wafer processes specify different degrees of acceptable contamination of the process liquid by particles and various metals. Depending upon the process specification, it may be possible to recover used process fluid and recondition it for reuse, which reduces operating costs. However, for other process specifications, the limits for acceptable metal and particle contamination are so low that fresh process liquid must be employed, and the contaminated process liquid discharged from the chuck must be led to drain and not reused. In this latter case, operating costs are significantly higher. It is furthermore expected that the acceptable limits for metal and particle contamination will continue to decrease with the decreasing feature size of the semiconductor devices formed on the wafers, especially in the case of front-end-of-line (FEOL) processing.

### SUMMARY OF THE INVENTION

The present inventors have developed improved processes and apparatus for liquid treatment of wafer-shaped articles, in which both fresh process liquid and recycled process liquid can be dispensed during a given process, and in which the sequence and timing of the supplies can be controlled as well as whether the discharged liquid from either supply is sent to drain or is recycled for further use. The processes and apparatus according to the invention therefore permit operating within very low particle and metal contamination limits, while minimizing operating cost.

Thus, the invention in one aspect relates to an apparatus for liquid treatment of wafer-shaped articles, comprising a process unit comprising a chuck for holding a wafer-shaped article in a predetermined orientation, a liquid recovery system that receives used process liquid recovered from the process unit and supplies process liquid to a dispenser in the process unit, and a supply of fresh process liquid that supplies fresh process liquid to the liquid recovery system and also supplies fresh process liquid to a dispenser in the process unit while bypassing the liquid recovery system.

In preferred embodiments of the apparatus according to the present invention, the liquid recovery system comprises a first tank having inlets for used process liquid recovered from the process unit and fresh process liquid supplied from the supply of fresh process liquid, and an outlet that is in liquid communication with at least a filter for conditioning process liquid supplied from the first tank. Also a thermostat (with a heater and/or cooler) can be provided.

In preferred embodiments of the apparatus according to the present invention, the liquid recovery system further comprises a first recirculation conduit that returns conditioned process liquid to the first tank while bypassing the dispenser for process liquid from the liquid recovery system. Such a first recirculation conduit (circuit) is used for thoroughly mixing and filtering the process liquid, keeping the process liquid in a constant flow and providing a given pressure of the process liquid near the dispenser.

In preferred embodiments of the apparatus according to the present invention, the supply of fresh process liquid comprises a second tank that is supplied with fresh process liquid separately from the liquid recovery system, the second tank having an outlet feeding fresh process liquid to at least a filter for conditioning process liquid supplied from the second tank. Also a thermostat (with a heater and/or cooler) can be provided.

In preferred embodiments of the apparatus according to the present invention, the supply of fresh process liquid further comprises a second recirculation conduit that returns conditioned process liquid to the second tank while bypassing the dispenser for process liquid from the supply of fresh process liquid.

In preferred embodiments of the apparatus according to the present invention, a first valve is provided for controlling flow of process liquid from the liquid recovery system to the dispenser, and a second valve is provided for controlling flow of process liquid from the supply of fresh process liquid to the dispenser. The first and second valves may be incorporated in a single valve assembly (e.g. a three-way valve). The apparatus according to these embodiments also includes a computer that is programmed to control the first and second valves so as to dispense process liquid from the liquid recovery system and from the supply of fresh process liquid in a predetermined process sequence. The computer is preferably programmed in order to directly and uninterruptedly switch from process liquid from the recovery system to fresh process liquid. With this system the wafer can be kept wet with the same process liquid and also for the last time sequence fresh process liquid is used.

In preferred embodiments of the apparatus according to the present invention, the dispenser supplied by the liquid recovery system and the dispenser supplied by the supply of fresh process liquid comprise a same dispensing nozzle, and the first and second valves are positioned upstream of the same dispensing nozzle.

In preferred embodiments of the apparatus according to the present invention, the chuck is surrounded by a liquid collector that comprises a discharge conduit that divides into a first branch leading to drain and a second branch leading to the liquid recovery system, and third and fourth valves are positioned in the first and second branches, respectively, for selectively directing liquid received from the liquid collector either to drain or to the liquid recovery system.

In preferred embodiments of the apparatus according to the present invention, the first recirculation circuit comprises a first backpressure valve that is controlled to regulate a recirculation flow into the first tank based upon a pressure of a feed of process liquid from the first tank to the dispenser.

In another aspect, the present invention provides a method for liquid treatment of wafer-shaped articles, comprising positioning a wafer-shaped article on a chuck in a predetermined orientation, and dispensing a process liquid onto the wafer-shaped article. The process liquid is supplied from a liquid recovery system. Used process liquid is recovered from a collector surrounding the chuck and the used process liquid is returned to the liquid recovery system. Fresh process liquid is supplied to the liquid recovery system and is also dispensed onto the wafer-shaped article while bypassing the liquid recovery system.

In preferred embodiments of the method according to the present invention, fresh process liquid is dispensed onto the wafer-shaped article while bypassing the liquid recovery system to generate contaminated process liquid, and the contaminated process liquid is discharged from the collector to a drain.

In preferred embodiments of the apparatus according to the present invention, after dispensing fresh process liquid onto the wafer-shaped article while bypassing the liquid recovery system, further process liquid is dispensed onto the wafer-shaped article from the liquid recovery system, and, after contacting the wafer-shaped article, the further process liquid is discharged from the collector to a recovery conduit that returns the further process liquid to the liquid recovery system.

In preferred embodiments of the apparatus according to the present invention, after dispensing further process liquid onto the wafer-shaped article from the liquid recovery system, fresh process liquid is again dispensed onto the wafer-shaped article while bypassing the liquid recovery system to generate contaminated process liquid, and the contaminated process liquid is discharged from the collector to a recovery conduit that leads the contaminated process liquid into the liquid recovery system.

In preferred embodiments of the apparatus according to the present invention, fresh process liquid is supplied to the liquid recovery system and dispensed from the liquid recovery system onto the wafer-shaped article to generate contaminated process liquid, and the contaminated process liquid is discharged from the collector to a drain.

In preferred embodiments of the apparatus according to the present invention, process liquid is recirculated within the liquid recovery system while bypassing the dispenser. The recirculating is effected at a flow rate that is adjusted as a function of a pressure of process liquid supplied from the liquid recovery system at a location proximate the dispensing.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is a schematic diagram of a first embodiment of the apparatus according to the present invention; and

FIG. 2 is a schematic diagram of a second embodiment of the apparatus according to the present invention

### DETAILED DESCRIPTION OF PREFERRED EMBODIMENTS

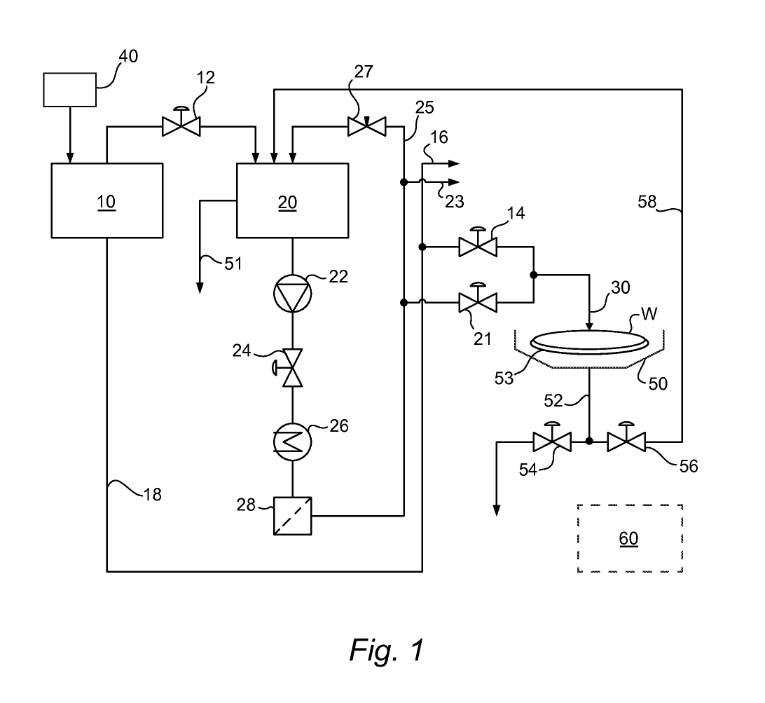

Referring now to FIG. 1, shown therein is an apparatus for liquid treatment of wafer-shaped articles according to a first embodiment of the invention. A process unit 50 comprises a chuck 53that holds a semiconductor wafer W in a predetermined orientation, which is typically with the axis of the wafer and the coincident rotational axis of the chuck oriented vertically or within a few degrees on either side of vertical. Chuck 53 is preferably a spin chuck for single wafer wet processing, and may be constructed for example as described in U.S. Pat. Nos. 4,903,717 and 5,513,668.

Chuck 53 may alternatively be constructed as described in commonly-owned U.S. Patent Application Pub. No. 2011/0253181 (corresponding to WO 2010/113089), in which case it will be appreciated that the wafer W will be suspended and depend downwardly from the magnetic rotor that constitutes the rotary part of the chuck.

The arrow 30 represents a liquid dispensing nozzle. Although nozzle 30 in FIG. 1 is positioned above the wafer W so as to dispense liquid onto the upwardly-facing surface of wafer W, those skilled in the art will recognize that nozzle 30 could instead be provided beneath the wafer W so as to dispense process liquid onto the downwardly-facing surface of wafer W, or that liquid dispensing nozzles may be provided on both sides of wafer W. Moreover, plural nozzles may be provided on either or both sides of the wafer W.

Process liquid to be dispensed from the nozzle 30 is initially supplied from a primary facility 40, to a tank mixing system 10. Tank mixing system 10 has an outlet communicating with conduit 18, and another outlet that supplies fresh process liquid into tank 20 through control valve 12. Conduit 18 is branched at a downstream location, with one branch leading to nozzle 30 through valve 14, and the other branch 16 leading to one or more additional process units. That is, the process liquid supply arrangement depicted in FIG. 1 may serve multiple process units, for example six or eight process units, with the process units being arranged in a group and similarly served by a common wafer handling unit and computer controller. Thus, branch 16 may in practice be a liquid manifold distributing process liquid to the plural process units individually or simultaneously.

Tank 20 forms part of the liquid recovery system according to this embodiment of the invention. Tank 20 has one outlet 51 leading to a drain for emptying of the tank, and a process outlet leading to pump 22. After passing through pump 22, process liquid fed from tank 20 passes through control valve 24 (when the valve is open), and then through heater 26 and filter 28. These latter two components condition the process liquid so that its physical properties are suitable for dispensing onto the wafer W.

After passing through the filter 28, the conduit carrying the conditioned process liquid branches at a downstream location, with one branch leading to nozzle 30 through valve 21. The other branch is further branched, with one branch 23 leading to one or more additional process units, or being a manifold for that purpose as described above in connection with element 16. The last branch leads into a recirculation conduit 25. Recirculation conduit 25 returns process liquid to the tank 20 through needle valve 27, while by bypassing the dispenser 30 and the manifold 23.

After process liquid is dispensed onto wafer W through nozzle 30, the spent or contaminated process liquid is discharged from the process unit 50 through conduit 52. Conduit 52 divides into two branches, each of which is provided with a respective control valve 54, 56. The branch with valve 54 leads to drain, whereas the branch with valve 56 leads to a conduit that returns the recovered process liquid to tank 20.

Each of the valves 12, 14, 21, 24, 27, 54 and 56 is controlled by computer controller 60, which also controls the spin chuck 53, pump 22 and heater 26.

Examples of the operation of the apparatus of FIG. 1 will now be described. In these examples, reclaim processing and processing-to-drain are combined in such a way that the most contaminated medium is drained, most of the processing time, the media is reclaimed in order to reduce operating cost, at the end of processing fresh medium is used to eliminate contamination, and bath exchange is not necessary.

In the following examples it is assumed that a given process sequence will occur over 60 seconds, for ease of explanation. Obviously in practice the duration of the process sequence may be shorter or longer, and the component stages of the sequence proportionately shorter or longer.

Fresh process liquid is supplied to the tank mixing system 10 from the primary facility 40. Next, valve 12 is opened and tank 20 is filled from the tank mixing system 10. Then, valves 14 and 54 are opened, with valves 21 and 56 remaining closed, so that fresh process liquid is dispensed through nozzle 30 onto wafer W with the highly contaminated process liquid going to drain, for a duration of 10 seconds. In a second stage, valves 14 and 54 are closed and valves 24, 21 and 56 are opened, so that process liquid is fed from tank 20 though pump 22, valve 24, heater 26, filter 28 and valve 21 so as to be dispensed through nozzle 30 onto wafer W with the contaminated process liquid being recycled through valve 56 and conduit 58, for a duration of 40 seconds.

As a final stage, for the last 10 seconds of the process sequence, valves 24 and 21 are closed and valve 14 is opened, whereas valve 56 remains open and valve 54 remains closed. Therefore, fresh process liquid is fed from the tank mixing system 10 and dispensed onto the wafer 30, while the resulting contaminated process liquid is recovered and recycled through the conduit 58.

In the first stage described above, the most contaminated process liquid is generated, and this liquid is not recycled. For the second stage, which represents the majority of the total process sequence, the process liquid is recycled. In the last stage, the introduction of fresh process liquid while recovering and recycling the resulting lightly contaminated process liquid, serves to eliminate contamination, such that exchange of the process liquid in the tank 20 is not necessary. Consequently, operating costs are significantly reduced while effectively controlling particle and metal contamination in the process liquid.

As a variation of the above-described process sequence, in the first stage the process liquid may be fed from the tank 20 to drain, rather than from the tank mixing system 10 to drain. In that case, valves 14 and 56 are closed whereas valves 24, 21 and 54 are open. The second and third stages are then run as described above.

Throughout the above-described process sequences, the needle valve 27 is controlled by computer controller 60 as a function of the pressure of the process liquid at valve 21. A suitable pressure sensor (not shown) reads the pressure at valve 21 and provides its readout to the computer controller 60.

For example, if tank 20 and pump 22 are feeding two or more process units simultaneously, the pressure at valve 21 would drop when valve 21 is open and a further valve (not shown) downstream of manifold 16 is open. In order to keep the liquid supply pressure constant in that case, the needle valve is closed to a relatively greater extent.

On the other hand, if no process liquid is being dispensed from tank 20, i.e., valve 21 is closed as well as all valves downstream of manifold 16, then valve 27 will be set to its fully open position, so that all process liquid is recirculated into the tank while bypassing dispenser 30 and any downstream dispensers.

An intermediate position of valve 27 would be set when one or more process units are dispensing process liquid supplied from tank 20, while one or more other process units are not.

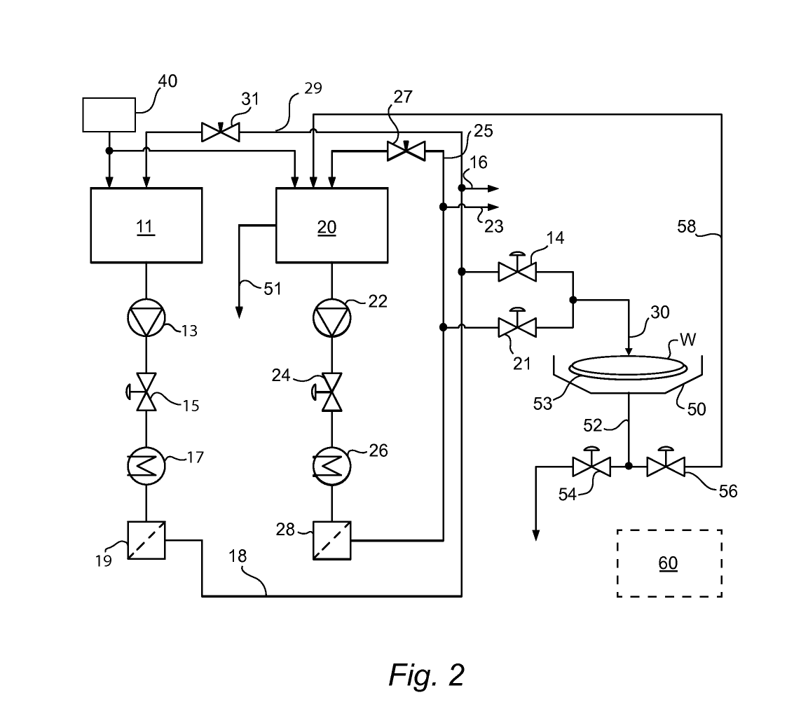

FIG. 2 shows a second embodiment of the apparatus according to the present invention. In this figure, elements like those of FIG. 1 are designated using the same reference numerals, and a description of those elements will not be repeated. In this embodiment, the tank mixing system has been replaced by a second tank 11, which contains fresh process liquid supplied from the primary facility 40. Tank 11 feeds process liquid through pump 13, valve 15, heater 17 and filter 19, so as to condition the process liquid as described above in connection with the conditioning equipment associated with tank 20.

Tank 11 in this embodiment similarly is provided with its own recirculation conduit 29 and needle valve 31, which is controlled by computer controller 60 in the manner described above in connection with valve 27. It will be noted that, in this embodiment, both tanks 11 and 20 are filled via the same conduit from primary facility 40, that is, fresh process liquid is not supplied to tank 20 via tank 11.

Although many different process sequences can be run with the apparatus of this embodiment, as is also the case for the apparatus of the previous embodiment, the following example is provided for purposes of illustration. Once again, in the following example, it is assumed that a given process sequence will occur over 60 seconds, for ease of explanation. Obviously in practice the duration of the process sequence may be shorter or longer, and the component stages of the sequence proportionately shorter or longer.

Fresh process liquid is supplied from the primary facility 40 so as to fill each of the tanks 11 and 20. Next, valves 21 and 54 are opened (valve 24 is preferably always open), with valves 15, 14 and 56 remaining closed, so that recycled process liquid from tank 20 is fed though pump 22, valve 24, heater 26, filter 28 and valve 21 so as to be dispensed through nozzle 30 onto wafer W, with the resulting highly contaminated process liquid going to drain, for a duration of 10 seconds.

In a second stage, valves 54 is closed and valve 56 is opened, while valves 15 and 14 remain closed and valves 24 and 21 remain opened, so that process liquid is fed from tank 20 though pump 22, valve 24, heater 26, filter 28 and valve 21 so as to be dispensed through nozzle 30 onto wafer W with the moderately contaminated process liquid being recycled through valve 56 and conduit 58, for a duration of 40 seconds.

As a final stage, for the last 10 seconds of the process sequence, valve 21 is closed and valves 15 and 14 are opened, whereas valve 56 remains open and valve 54 remains closed. Therefore, fresh process liquid is fed from the tank 11 though pump 13, valve 15, heater 17, filter 19 and valve 14 so as to be dispensed through nozzle 30 onto the wafer W, while the resulting lightly contaminated process liquid is recovered and recycled through the conduit 58.

As was true of the previous embodiment, in the first stage described above, the most contaminated process liquid is generated, and this liquid is not recycled. For the second stage, which represents the majority of the total process sequence, the process liquid is recycled. In the last stage, the introduction of fresh process liquid while recovering and recycling the resulting lightly contaminated process liquid, serves to eliminate contamination, such that exchange of the process liquid in the tank 20 is not necessary. Consequently, operating costs are significantly reduced while effectively controlling particle and metal contamination in the process liquid.

What is claimed is:

1. An apparatus for liquid treatment of wafer-shaped articles, comprising a process unit comprising a chuck for holding a wafer-shaped article in a predetermined orientation, a liquid recovery system that receives used process liquid recovered from the process unit and supplies process liquid to a dispenser in the process unit, and a supply of fresh process liquid that supplies fresh process liquid to the liquid recovery system and also supplies fresh process liquid to a dispenser in the process unit while bypassing the liquid recovery system.

2. The apparatus according to claim 1, wherein said liquid recovery system comprises a first tank having inlets for used process liquid recovered from the process unit and fresh process liquid supplied from said supply of fresh process liquid, and an outlet that is in liquid communication with at least a filter for conditioning process liquid supplied from said first tank.

3. The apparatus according to claim 2, wherein said liquid recovery system further comprises a first recirculation conduit that returns conditioned process liquid to said first tank while bypassing said dispenser for process liquid from said liquid recovery system.

4. The apparatus according to claim 1, wherein said supply of fresh process liquid comprises a second tank that is supplied with fresh process liquid separately from said liquid recovery system, said second tank having an outlet feeding fresh process liquid to at least a heater and a filter for conditioning process liquid supplied from said second tank.

5. The apparatus according to claim 4, wherein said supply of fresh process liquid further comprises a second recirculation conduit that returns conditioned process liquid to said second tank while bypassing said dispenser for process liquid from said supply of fresh process liquid.

6. The apparatus according to claim 1, further comprising a first valve for controlling flow of process liquid from said liquid recovery system to said dispenser, a second valve for controlling flow of process liquid from said supply of fresh process liquid to said dispenser, and a computer that is programmed to control said first and second valves so as to dispense process liquid from said liquid recovery system and from said supply of fresh process liquid in a predetermined process sequence.

7. The apparatus according to claim 6, wherein said dispenser supplied by the liquid recovery system and said dispenser supplied by the supply of fresh process liquid comprise a same dispensing nozzle, and wherein said first and second valves are positioned upstream of said same dispensing nozzle.

8. The apparatus according to claim 1, wherein said process unit comprises a discharge conduit that divides into a first branch leading to drain and a second branch leading to said liquid recovery system, and wherein third and fourth valves are positioned in said first and second branches, respectively, for selectively directing liquid received from the liquid collector either to drain or to said liquid recovery system.

9. The apparatus according to claim 3, wherein said first recirculation circuit comprises a first backpressure valve that is controlled to regulate a recirculation flow into said first tank based upon a pressure of a feed of process liquid from said first tank to said dispenser.

10. A method for liquid treatment of wafer-shaped articles, comprising positioning a wafer-shaped article on a chuck in a predetermined orientation, dispensing a process liquid onto the wafer-shaped article, the process liquid being supplied from a liquid recovery system, recovering used process liquid from a liquid collector surrounding the chuck and returning the used process liquid to the liquid recovery system, and supplying fresh process liquid to the liquid recovery system and also dispensing fresh process liquid onto the wafer-shaped article while bypassing the liquid recovery system.

11. The method according to claim 10, wherein fresh process liquid is dispensed onto the wafer-shaped article while bypassing the liquid recovery system to generate contaminated process liquid, and the contaminated process liquid is discharged from the liquid collector to a drain.

12. The method according to claim 11, wherein, after dispensing fresh process liquid onto the wafer-shaped article while bypassing the liquid recovery system, further process liquid is dispensed onto the wafer-shaped article from the liquid recovery system, and, after contacting the wafer-shaped article, the further process liquid is discharged from the liquid collector to a recovery conduit that returns the further process liquid to the liquid recovery system.

13. The method according to claim 12, wherein, after dispensing further process liquid onto the wafer-shaped article from the liquid recovery system, fresh process liquid is again dispensed onto the wafer-shaped article while bypassing the liquid recovery system to generate contaminated process liquid, and the contaminated process liquid is discharged from the liquid collector to a recovery conduit that leads the contaminated process liquid into the liquid recovery system.

14. The method according to claim 10, wherein fresh process liquid is supplied to the liquid recovery system and dispensed from the liquid recovery system onto the wafer-shaped article to generate contaminated process liquid, and the contaminated process liquid is discharged from the liquid collector to a drain.

15. The method according to claim 10, further comprising recirculating process liquid within the liquid recovery system while bypassing the dispenser, wherein said recirculating is effected at a flow rate that is adjusted as a function of a pressure of process liquid supplied from the liquid recovery system at a location proximate said dispensing.
